(19) United States
(12) Patent Application Publication
(10) Pub. No.: US 2018/0264783 A1
(43) Pub. Date: Sep. 20, 2018

(54) Metal Foil, Metal Foil Having Release Layer, Laminated Material, Printed Wiring Board, Semiconductor Package, Electronic Device, And Method For Producing Printed Wiring Board

(71) Applicant: JX Nippon Mining & Metals Corporation, Chiyoda-ku, Tokyo (JP)

(72) Inventors: Terumasa Moriyama, Ibaraki (JP); Masafumi Ishii, Ibaraki (JP)

(21) Appl. No.: 15/761,274

(22) PCT Filed: Sep. 23, 2016
(86) PCT No.: PCT/JP2016/078118

§ 371 Date: Mar. 19, 2018

(30) Foreign Application Priority Data
Sep. 24, 2015 (JP) 2015-187491

(51) Int. Cl. B32B 15/08; B32B 15/20; C25D 1/04; C25D 1/22; C25D 7/06; C25D 5/16; H05K 3/38; H05K 3/46

(52) U.S. Cl. CPC B32B 15/08; B32B 15/20; C25D 1/04; C25D 1/22; H05K 2201/0355; C25D 5/16; H05K 3/384; H05K 3/46; C25D 7/0614

(57) ABSTRACT

Such a metal foil is provided that a release layer is provided on a metal foil to enable physical release of a resin substrate, to which the metal foil is adhered, and thereby in the step of removing the metal foil from the resin substrate, the metal foil can be removed with good cost without damaging the surface profile of the metal foil transferred to the surface of the resin substrate, and also resins having different resin components can be adhered with good adhesion. A metal foil containing, on at least one surface of the metal foil, surface unevenness having a root mean square height Sq of from 0.25 to 1.6 μm.

### TECHNICAL FIELD

The present invention relates to a metal foil, a metal foil having a release layer, a laminated material, a printed wiring board, a semiconductor package, an electronic device, and a method for producing a printed wiring board.

### BACKGROUND ART

While the mainstream of the method for forming a circuit of a printed wiring board or a semiconductor package board is the subtractive process, new processes including M-SAP (modified semi-additive process) and a semi-additive process using a surface profile of a metal foil are becoming dominant associated with the recent increasing miniaturization of wiring.

Among the new circuit forming processes, an example of the latter semi-additive process using a surface profile of a metal foil is as follows. Specifically, a metal foil laminated on a resin substrate is etched for the whole surface thereof, holes are formed with laser in the etched substrate surface having the surface profile of the metal foil transferred thereto, an electroless copper plated layer is applied for conducting the hole portions, the surface of the electroless copper plated layer is covered with a dry film, the dry film is removed through UV exposure and development for the circuit forming portion, copper electroplating is applied to the surface of the electroless copper plated layer that is not covered with the dry film, the dry film is removed, and finally the electroless copper plated layer is etched with an etching solution containing sulfuric acid and a hydrogen peroxide solution or the like (such as flash etching and quick etching), thereby forming a fine circuit (see PTLs 1 and 2).

### CITATION LIST

### Patent Literatures

[PTL 1] JP-A-2006-196863

[PTL 2] JP-A-2007-242975

### SUMMARY OF INVENTION

### Technical Problem

However, in the ordinary semi-additive process using a surface profile of a metal foil, there is still room for improvement in the favorable transfer of the surface profile of the metal foil to the surface of the resin substrate without damage, and in the removal of the metal foil with good cost.

In recent years, furthermore, techniques for producing a laminated material formed by laminating a resin and another resin have been studied and developed. There are cases therein that sufficient adhesion cannot be obtained with different resin components, and it is necessary to enhance the adhesion through an anchoring effect by providing unevenness on one of the resins. The methods for providing unevenness on the surface of the cured resin include a physical method, a chemical method, and the like, but there are cases where these methods are not suitable due to the physical properties and the chemical properties of the resin. Accordingly, a further development is demanded for a technique for adhering resins having different resin components with good adhesion.

### Solution to Problem

As a result of earnest investigations made by the present inventors, it has been found that a release layer is provided on a metal foil having surface unevenness to enable physical release of a resin substrate, to which the metal foil is adhered, and thereby in the step of removing the metal foil from the resin substrate, the metal foil can be removed with good cost without damaging the surface profile of the metal foil transferred to the surface of the resin substrate. Furthermore, it has been found that a metal foil having prescribed surface unevenness having good adhesion to a resin is adhered and cured on the resin, followed by transferring the unevenness to the surface of the resin by removing the metal foil, and thereby resins having different resin components can be adhered with good adhesion.

The invention having been completed based on the knowledge relates to, in one aspect, a metal foil containing, on at least one surface of the metal foil, surface unevenness having a root mean square height Sq of from 0.25 to 1.6 μm.

The invention relates to, in another aspect, a metal foil containing, on at least one surface of the metal foil, surface unevenness having a ratio (Sq/Rsm) of a root mean square height Sq to an average interval Rsm of the roughness of from 0.05 to 0.40.

In the metal foil of the invention in one embodiment, the metal foil contains, on at least one surface of the metal foil, surface unevenness having a ratio (Sq/Rsm) of a root mean square height Sq to an average interval Rsm of the roughness of from 0.05 to 0.40.

In the metal foil of the invention in one embodiment, the metal foil has a thickness of from 5 to 105 μm.

In the metal foil of the invention in another embodiment, the metal foil is a copper foil.

In the metal foil of the invention in still another embodiment, the metal foil contains, on a surface of the metal foil, one or more layer selected from the group consisting of a roughening treatment layer, a heat resistant layer, a rust preventing layer, a chromate treatment layer, and a silane coupling treatment layer.

In the metal foil of the invention in still another embodiment, the metal foil contains a resin layer on the one or more layer selected from the group consisting of a roughening treatment layer, a heat resistant layer, a rust preventing layer, a chromate treatment layer, and a silane coupling treatment layer.

In the metal foil of the invention in still another embodiment, the resin layer is an adhesive resin, a primer, or a semi-cured resin.

The invention relates to, in another aspect, a metal foil having a release layer containing the metal foil of the invention and a release layer provided on a side of the metal foil having the surface unevenness, wherein the release layer enables release of a resin substrate when the resin substrate is adhered to the metal foil on a side of the release layer.

In the metal foil having a release layer of the invention in one embodiment, the release layer contains one kind or a combination of plural kinds of an aluminate compound, a titanate compound, or a zirconate compound represented by the following formula, a hydrolyzed product of the aluminate compound, the titanate compound, or the zirconate compound, and a condensed product of the hydrolyzed product:

(R¹)ₘ-M-(R²)ₙ

wherein R¹ represents an alkoxy group or a halogen atom; R² represents a hydrocarbon group selected from the group consisting of an alkyl group, a cycloalkyl group, and an aryl group, or the hydrocarbon group, in which one or more hydrogen atom is substituted by a halogen atom; M represents any one of Al, Ti, and Zr; n represents 0, 1, or 2; and m represents an integer of 1 or more and a valency of M or less, provided that at least one of R¹ is an alkoxy group, and m+n is a valency of M, which is 3 for Al or 4 for Ti and Zr.

In the metal foil having a release layer of the invention in another embodiment, the release layer contains one kind or a combination of plural kinds of a silane compound represented by the following formula, a hydrolyzed product of the silane compound, and a condensed product of the hydrolyzed product:

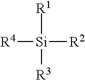

wherein R¹ represents an alkoxy group or a halogen atom; R² represents a hydrocarbon group selected from the group consisting of an alkyl group, a cycloalkyl group, and an aryl group, or the hydrocarbon group, in which one or more hydrogen atom is substituted by a halogen atom; R³ and R⁴ each independently represent a halogen atom, an alkoxy group, a hydrocarbon group selected from the group consisting of an alkyl group, a cycloalkyl group, and an aryl group, or the hydrocarbon group, in which one or more hydrogen atom is substituted by a halogen atom.

In the metal foil having a release layer of the invention in still another embodiment, the release layer contains a compound containing two or less mercapto groups in a molecule.

In the metal foil having a release layer of the invention in still another embodiment, the metal foil having a release layer contains a resin layer provided on a surface of the release layer.

In the metal foil having a release layer of the invention in still another embodiment, the resin layer is an adhesive resin, a primer, or a semi-cured resin.

The invention relates to, in still another aspect, a laminated material containing the metal foil of the invention or the metal foil having a release layer of the invention and a resin substrate provided on the metal foil or the metal foil having a release layer.

In the laminated material of the invention in one embodiment, the resin substrate is a prepreg or contains a thermosetting resin.

The invention relates to, in still another aspect, a printed wiring board containing the metal foil of the invention or the metal foil having a release layer of the invention.

The invention relates to, in still another aspect, a semiconductor package containing the printed wiring board of the invention.

The invention relates to, in still another aspect, an electronic device containing the printed wiring board of the invention or the semiconductor package of the invention.

The invention relates to, in still another aspect, a method for producing a printed wiring board, containing: adhering a resin substrate to the metal foil of the invention or the metal foil having a release layer of the invention; releasing the metal foil or the metal foil having a release layer without etching, from the resin substrate, so as to provide a resin substrate having a surface profile of the metal foil or the metal foil having a release layer, transferred to a released surface of the resin substrate; and forming a circuit on the released surface of the resin substrate having the surface profile transferred.

In the method for producing a printed wiring board of the invention in one embodiment, the circuit formed on the released surface of the resin substrate having the surface profile transferred is a plated pattern or a printed pattern.

The invention relates to, in still another aspect, a method for producing a printed wiring board, containing: adhering a resin substrate to the metal foil of the invention or the metal foil having a release layer of the invention; releasing the metal foil or the metal foil having a release layer without etching, from the resin substrate, so as to provide a resin substrate having a surface profile of the metal foil or the metal foil having a release layer, transferred to a released surface of the resin substrate; and providing a build-up layer on the released surface of the resin substrate having the surface profile transferred.

In the method for producing a printed wiring board of the invention in one embodiment, a resin constituting the build-up layer contains a liquid crystal polymer or polytetrafluoroethylene.

### Advantageous Effects of Invention

A release layer is provided on a metal foil to enable physical release of a resin substrate, to which the metal foil is adhered, and thereby in the step of removing the metal foil from the resin substrate, the metal foil can be removed with good cost without damaging the surface profile of the metal foil transferred to the surface of the resin substrate. Furthermore, resins having different resin components can be adhered with good adhesion.

### BRIEF DESCRIPTION OF DRAWING

FIG. 1 is a schematic example of a semi-additive process using a profile of a copper foil.

### DESCRIPTION OF EMBODIMENT

### Metal Foil and Metal Foil Having Release Layer

The metal foil of the invention in one aspect is a metal foil containing, on at least one surface of the metal foil, i.e., on one surface or both surfaces thereof, surface unevenness having a root mean square height Sq of from 0.25 to 1.6 μm.

The metal foil having a release layer of the invention is a metal foil having a release layer containing the metal foil of the invention and a release layer provided on a side of the metal foil having the surface unevenness, wherein the release layer enables release of a resin substrate when the resin substrate is adhered to the metal foil on a side of the release layer.

As described above, the release layer is provided on the metal foil to enable physical release of the resin substrate, to which the metal foil is adhered, and thereby in the step of removing the metal foil from the resin substrate, the metal foil can be removed with good cost without damaging the surface profile of the metal foil transferred to the surface of the resin substrate.

In the description herein, in the case where a surface treatment layer, such as a roughening treatment layer, a heat resistant layer, a rust preventing layer, a chromate treatment layer, and a silane coupling treatment layer, on the surface of the metal foil, the “surface” and the “surface of the metal foil” means the surface after providing the surface treatment layer (i.e., the surface of the outermost layer).

The metal foil of the invention has on the surface of the metal foil, surface unevenness having a root mean square height Sq of from 0.25 to 1.6 μm, and thereby while retaining the good releasability after adhering the metal foil and a resin substrate, a laminating member, such as a circuit, a resin and a build-up layer, can follow the surface of the resin substrate without a gap (or with an extremely small gap) by the unevenness shape transferred to the surface of the resin substrate after releasing the metal foil, so as to enable to provide the laminating member, such as a circuit, a resin and a build-up layer, on the surface of the resin substrate with good adhesion.

When the root mean square height Sq is less than 0.25 μm, the problem arises that the unevenness on the surface of the resin substrate obtained by adhering the metal foil and the resin substrate and then releasing the metal foil is small, and thereby the adhesion to a different resin becomes insufficient, and when the root mean square height Sq exceeds 1.6 μm, the problem arises that the releasability on releasing the metal foil after adhering the metal foil and the resin substrate is deteriorated, and furthermore the laminating member, such as a circuit, a resin and a build-up layer, cannot follow the unevenness shape on the surface of the resin substrate after releasing the metal foil since the unevenness shape is too deep. The root mean square height Sq is preferably from 0.30 to 1.4 μm, more preferably from 0.4 to 1.0 μm, and further preferably from 0.4 to 0.96 μm.

The metal foil of the invention in another aspect is a metal foil containing, on at least one surface of the metal foil, i.e., on one surface or both surfaces thereof, surface unevenness having a ratio (Sq/Rsm) of a root mean square height Sq to an average interval Rsm of the roughness of from 0.05 to 0.40.

The metal foil having a release layer of the invention is a metal foil having a release layer containing the metal foil and a release layer provided on a side of the metal foil having the surface unevenness, wherein the release layer enables release of a resin substrate when the resin substrate is adhered to the metal foil on a side of the release layer.

As described above, the release layer is provided on the metal foil to enable physical release of the resin substrate, to which the metal foil is adhered, and thereby in the step of removing the metal foil from the resin substrate, the metal foil can be removed with good cost without damaging the surface profile of the metal foil transferred to the surface of the resin substrate.

The metal foil of the invention has on the surface of the metal foil, surface unevenness having a ratio (Sq/Rsm) of a root mean square height Sq to an average interval Rsm of the roughness of from 0.05 to 0.40, and thereby while retaining the good releasability after adhering the metal foil and a resin substrate, a laminating member, such as a circuit, a resin and a build-up layer, can follow the surface of the resin substrate without a gap (or with an extremely small gap) by the unevenness shape transferred to the surface of the resin substrate after releasing the metal foil, so as to enable to provide the laminating member, such as a circuit, a resin and a build-up layer, on the surface of the resin substrate with good adhesion.

When the ratio (Sq/Rsm) of the root mean square height Sq to the average interval Rsm of the roughness is less than 0.05, the problem arises that the unevenness on the surface of the resin substrate obtained by adhering the metal foil and the resin substrate and then releasing the metal foil is small, and thereby the adhesion to a different resin becomes insufficient, and when the ratio (Sq/Rsm) exceeds 0.40, the problem arises that the releasability on releasing the metal foil after adhering the metal foil and the resin substrate is deteriorated, and furthermore the laminating member, such as a circuit, a resin and a build-up layer, cannot follow the unevenness shape on the surface of the resin substrate after releasing the metal foil since the unevenness shape is too deep. The ratio (Sq/Rsm) of the root mean square height Sq to the average interval Rsm of the roughness is preferably from 0.10 to 0.25, and more preferably from 0.10 to 0.20.

The release layer may be provided on both surfaces of the metal foil. The adhesion or lamination of the metal foil and the resin substrate, and the lamination of the laminating member, such as a circuit, a resin and a build-up layer, on the resin substrate may be performed by press bonding.

The metal foil (which may also be referred to as a raw foil) is not particularly limited, and a copper foil, an aluminum foil, a nickel foil, a copper alloy foil, a nickel alloy foil, an aluminum alloy foil, a stainless steel foil, an iron foil, an iron alloy foil, and the like may be used.

The thickness of the metal foil (raw foil) is not particularly limited, and may be, for example, from 5 to 105 μm. The thickness of the metal foil is preferably from 9 to 70 μm, more preferably from 12 to 35 μm, and further preferably from 18 to 35 μm, since the metal foil can be easily released from the resin substrate.

A copper foil as an example of the metal foil (raw foil) will be described. The production method of the metal foil (raw foil) is not particularly limited, and for example, an electrolytic copper foil can be produced by the following electrolysis condition.
Electrolysis condition of electrolytic raw foil:

Composition of electrolytic solution:
Cu: 30 to 190 g/L
H₂SO₄: 100 to 400 g/L
Chloride ion (Cl⁻): 60 to 200 ppm by mass
Glue: 1 to 10 ppm
((3-Sulfopropyl) disulfide (SPS): 10 to 100 ppm depending on necessity

Temperature of electrolysis solution: 25 to 80° C.

Electrolysis time: 10 to 300 seconds (controlled depending on copper thickness to be deposited and electric current density)

Electric current density: 50 to 150 A/dm²

Linear velocity of electrolysis solution: 1.5 to 5 m/sec

In the description herein, the balance of the solution, such as the electrolytic solution, the plating solution, the silane coupling treatment solution, and the solution used for forming a release layer, and the treatment solution for the surface treatment is water unless otherwise indicated.

Both the root mean square height Sq and the ratio (Sq/Rsm) of the Sq to the average interval Rsm of the roughness can be controlled by the aforementioned electrolysis condition. When the electrolysis time (copper thickness) and/or the electric current density are increased within the range, the Sq and the Sq/Rsm are increased. When the chloride ion concentration, the glue concentration, the SPS concentration, and/or the linear velocity of the electrolytic solution are increased within the ranges, there is a tendency that the Sq and the Sq/Rsm are decreased. The electrolysis condition may be controlled corresponding to the target extent of the releasability and the target adhesion to the laminating member.

In the invention, the removal of the metal foil from the resin substrate means that the metal foil is removed from the resin substrate by a chemical treatment, such as etching, or the resin substrate is released physically from the metal foil by peeling or the like. When the resin substrate is adhered to the metal foil and then removed therefrom as described above, the resin substrate and the metal foil is released from each other at the release layer. At this time, the release layer, and a roughening treatment layer, a heat resistant layer, a rust preventing layer, a chromate treatment layer, a silane coupling treatment layer, and the like of the metal foil described later may partially remain on the released surface of the resin substrate, and preferably do not remain thereon.

The metal foil according to the invention preferably has a release strength on adhering to the resin substrate and then releasing the resin substrate of 200 gf/cm or less. By controlling the release strength in this manner, the resin substrate can be easily physically released, and the surface profile of the metal foil can be more favorably transferred to the resin substrate. The release strength is more preferably 150 gf/cm or less, further preferably 100 gf/cm or less, and still further preferably 50 gf/cm or less, and is typically from 1 to 200 gf/cm, and more typically from 1 to 150 gf/cm.

The release layer that can be used in the invention will be described.

### (1) Silane Compound

The release layer may be formed with one kind or a combination of plural kinds of a silane compound represented by the following formula, a hydrolyzed product of the silane compound, and a condensed product of the hydrolyzed product (which are hereinafter referred simply to a silane compound), and thereby on adhering the metal foil and the resin substrate, the adhesion can be appropriately decreased to control the release strength to the aforementioned range.

### Formula:

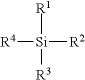

In the formula, R¹ represents an alkoxy group or a halogen atom; R² represents a hydrocarbon group selected from the group consisting of an alkyl group, a cycloalkyl group, and an aryl group, or the hydrocarbon group, in which one or more hydrogen atom is substituted by a halogen atom; R³ and R⁴ each independently represent a halogen atom, an alkoxy group, a hydrocarbon group selected from the group consisting of an alkyl group, a cycloalkyl group, and an aryl group, or the hydrocarbon group, in which one or more hydrogen atom is substituted by a halogen atom.

The silane compound necessarily has at least one alkoxy group. In the case where no alkoxy group is present, and the substituents are constituted only by a hydrocarbon group selected from the group consisting of an alkyl group, a cycloalkyl group, and an aryl group, or the hydrocarbon group, in which one or more hydrogen atom is substituted by a halogen atom, there is a tendency that the adhesion of the resin substrate and the metal foil is excessively decreased. The silane compound necessarily has at least one of a hydrocarbon group selected from the group consisting of an alkyl group, a cycloalkyl group, and an aryl group, and the hydrocarbon group, in which one or more hydrogen atom is substituted by a halogen atom. In the case where the hydrocarbon group is not present, there is a tendency that the adhesion of the resin substrate and the metal foil is increased. The alkoxy group herein encompasses an alkoxy group, in which one or more hydrogen atom is substituted by a halogen atom.

For controlling the release strength of the resin substrate and the metal foil to the aforementioned range, the silane compound preferably has three of the alkoxy groups and one of the hydrocarbon group (including the hydrocarbon group, in which one or more hydrogen atom is substituted by a halogen atom). As this is applied to the aforementioned formula, both R³ and R⁴ each are an alkoxy group.

The alkoxy group is not limited, and examples thereof include a linear, branched, or cyclic alkoxy group having a number of carbon atoms of from 1 to 20, preferably a number of carbon atoms of from 1 to 10, and more preferably a number of carbon atoms of from 1 to 5, such as a methoxy group, an ethoxy group, a n- or iso-propoxy group, a n-, iso-, or tert-butoxy group, a n-, iso-, or neo-pentoxy group, a n-hexyloxy group, a cyclohexyloxy group, a n-heptyloxy group, and a n-octyloxy group.

Examples of the halogen atom include a fluorine atom, a chlorine atom, a bromine atom, and an iodine atom.

The alkyl group is not limited, and examples thereof include a linear or branched alkyl group having a number of carbon atoms of from 1 to 20, preferably a number of carbon atoms of from 1 to 10, and more preferably a number of carbon atoms of from 1 to 5, such as a methyl group, an ethyl group, a n- or iso-propyl group, a n-, iso-, or tert-butyl group, a n-, iso-, or neo-pentyl group, a n-hexyl group, a n-octyl group, and a n-decyl group.

The cycloalkyl group is not limited, and examples thereof include a cycloalkyl group having a number of carbon atoms of from 3 to 10, and preferably a number of carbon atoms of from 5 to 7, such as a cyclopropyl group, a cyclobutyl group, a cyclopentyl group, a cyclohexyl group, a cycloheptyl group, and a cyclooctyl group.

Examples of the aryl group include an aryl group having a number of carbon atoms of from 6 to 20, and preferably a number of carbon atoms of from 6 to 14, such as a phenyl group, a phenyl group substituted by an alkyl group (such as a tolyl group and a xylyl group), a 1- or 2-naphthyl group, and an anthryl group.

In the hydrocarbon group, one or more hydrogen atom may be substituted by a halogen atom, and for example, may be substituted by a fluorine atom, a chlorine atom, or a bromine atom.

Preferred examples of the silane compound include methyltrimethoxysilane, ethyltrimethoxysilane, n- or iso-propyltrimethoxysilane, n-, iso-, or tert-butyltrimethoxysilane, n-, iso-, or neo-pentyltrimethoxysilane, hexyltrimethoxysilane, octyltrimethoxysilane, decyltrimethoxysilane, phenyltrimethoxysilane, an alkyl-substituted phenyltrimethoxysilane (such as p-(methyl)phenyltrimethoxysilane), methyltriethoxysilane, ethyltriethoxysilane, n- or iso-propyltriethoxysilane, n-, iso-, or tert-butyltriethoxysilane, pentyltriethoxysilane, hexyltriethoxysilane, octyltriethoxysilane, decyltriethoxysilane, phenyltriethoxysilane, an alkyl-substituted phenyltriethoxysilane (such as p-(methyl)phenyltriethoxysilane), (3,3,3-trifluoropropyl)trimethoxysilane, tridecafluorooctyltriethoxysilane, methyltrichlorosilane, dimethyldichlorosilane, trimethylchlorosilane, phenyltrichlorosilane, trimethylfluorosilane, dimethyldibromosilane, diphenyldibromosilane, hydrolyzed products of the silane compounds, and condensed products of the hydrolyzed products. Among these, propyltrimethoxysilane, methyltriethoxysilane, hexyltrimethoxysilane, phenyltriethoxysilane, and decyltrimethoxysilane are preferred from the standpoint of the availability.

In the step of forming the release layer, the silane compound may be used in the form of an aqueous solution. For enhancing the solubility to water, an alcohol, such as methanol and ethanol, may be added. The addition of an alcohol is effective particularly in the case where the silane compound having high hydrophobicity is used. In the aqueous solution of the silane compound, the hydrolysis of the alkoxy group is accelerated by agitation, and the condensation of the hydrolyzed product is accelerated when the agitation time is prolonged. In general, the use of the silane compound, in which the hydrolysis and the condensation proceed with a sufficient agitation time, may provide a tendency that the release strength of the resin substrate and the metal foil is decreased. Accordingly, the release strength can be controlled by controlling the agitation time. The agitation time after dissolving the silane compound in water is not limited, and may be, for example, from 1 to 100 hours, and typically from 1 to 30 hours. Naturally, the aqueous solution may be used without agitation.

When the concentration of the silane compound in the aqueous solution of the silane compound is large, there is a tendency that the release strength of the metal foil and the plate carrier is decreased, and the release strength can be controlled by controlling the concentration of the silane compound. The concentration of the silane compound in the aqueous solution is not limited, and may be from 0.01 to 10.0% by volume, and typically from 0.1 to 5.0% by volume.

The pH of the aqueous solution of the silane compound is not particularly limited, and the aqueous solution may be used as acidic or alkaline. For example, the aqueous solution may be used in a pH range of from 3.0 to 10.0. The pH is preferably around neutral in a range of from 5.0 to 9.0, and more preferably in a range of from 7.0 to 9.0, from the standpoint that any particular control of the pH is not necessary.

### (2) Compound Containing Two or Less Mercapto Groups in Molecule

The release layer may be constituted by a compound containing two or more mercapto groups in the molecule, and the resin substrate and the metal foil may be adhered through the release layer, thereby appropriately decreasing the adhesion and controlling the release strength.

However, the case where the resin substrate and the metal foil are adhered with a compound containing three or more mercapto groups in the molecule or a salt of the compound intervening between them is not suitable for the purpose of decreasing the release strength. This is because it is considered that when mercapto groups are present in the molecule in an excessive amount, sulfide bonds, disulfide bonds, and polysulfide bonds are formed excessively through chemical reaction between the mercapto groups and between the mercapto group and the plate carrier, and a firm three-dimensional crosslinked structure is formed between the resin substrate and the metal foil, which increases the release strength. An example of the case is described in JP-A-2000-196207.

Examples of the compound containing two or less mercapto groups in the molecule include a thiol, a dithiol, a thiocarboxylic acid and a salt thereof, a dithiocarboxylic acid and a salt thereof, a thiosulfonic acid and a salt thereof, and a dithiosulfonic acid and a salt thereof, and at least one selected from these compounds may be used.

The thiol has one mercapto group in the molecule, and is represented, for example, by R—SH, wherein R represents an aliphatic or aromatic hydrocarbon group or a heterocyclic group, which may contain a hydroxyl group or an amino group.

The dithiol has two mercapto groups in the molecule, and is represented, for example, by R(SH)₂, wherein R represents an aliphatic or aromatic hydrocarbon group or a heterocyclic group, which may contain a hydroxyl group or an amino group. The two mercapto groups may be bonded to the same carbon atom or may be bonded to different carbon atoms respectively.

The thiocarboxylic acid is an organic carboxylic acid, in which the hydroxyl group is substituted by a mercapto group, and is represented, for example, by R—CO—SH, wherein R represents an aliphatic or aromatic hydrocarbon group or a heterocyclic group, which may contain a hydroxyl group or an amino group. The thiocarboxylic acid may be used in the form of a salt. A compound containing two thiocarboxylic acid groups may also be used.

The dithiocarboxylic acid is an organic carboxylic acid, in which two oxygen atoms in the carboxyl group are substituted by sulfur atoms, and is represented, for example, by R—(CS)—SH, wherein R represents an aliphatic or aromatic hydrocarbon group or a heterocyclic group, which may contain a hydroxyl group or an amino group. The dithiocarboxylic acid may be used in the form of a salt. A compound containing two dithiocarboxylic acid groups may also be used.

The thiosulfonic acid is an organic sulfonic acid, in which the hydroxyl group is substituted by a mercapto group, and is represented, for example, by R—(SO₂)—SH, wherein R represents an aliphatic or aromatic hydrocarbon group or a heterocyclic group, which may contain a hydroxyl group or an amino group. The thiosulfonic acid may be used in the form of a salt.

The dithiosulfonic acid is an organic sulfonic acid, in which two hydroxyl groups are substituted by sulfur atoms, and is represented, for example, by R—((SO₂)—SH)₂, wherein R represents an aliphatic or aromatic hydrocarbon group or a heterocyclic group, which may contain a hydroxyl group or an amino group. The two thiosulfonic acid groups may be bonded to the same carbon atom or may be bonded to different carbon atoms respectively. The dithiosulfonic acid may be used in the form of a salt.

Examples of the aliphatic hydrocarbon group that is preferred as R include an alkyl group and a cycloalkyl group, and the hydrocarbon group may contain one or both of a hydroxyl group or an amino group.

The alkyl group is not limited, and examples thereof include a linear or branched alkyl group having a number of carbon atoms of from 1 to 20, preferably a number of carbon atoms of from 1 to 10, and more preferably a number of carbon atoms of from 1 to 5, such as a methyl group, an ethyl group, a n- or iso-propyl group, a n-, iso-, or tert-butyl group, a n-, iso-, or neo-pentyl group, a n-hexyl group, a n-octyl group, and a n-decyl group.

The cycloalkyl group is not limited, and examples thereof include a cycloalkyl group having a number of carbon atoms of from 3 to 10, and preferably a number of carbon atoms of from 5 to 7, such as a cyclopropyl group, a cyclobutyl group, a cyclopentyl group, a cyclohexyl group, a cycloheptyl group, and a cyclooctyl group.

Examples of the aromatic hydrocarbon group that is preferred as R include an aryl group having a number of carbon atoms of from 6 to 20, and preferably a number of carbon atoms of from 6 to 14, such as a phenyl group, a phenyl group substituted by an alkyl group (such as a tolyl group and a xylyl group), a 1- or 2-naphthyl group, and an anthryl group, and the hydrocarbon group may contain one or both of a hydroxyl group or an amino group.

Examples of the heterocyclic group that is preferred as R include imidazole, triazole, tetrazole, benzimidazole, benzotriazole, thiazole, and benzothiazole, and the heterocyclic group may contain one or both of a hydroxyl group or an amino group.

Preferred examples of the compound containing two or less mercapto groups in the molecule include 3-mercapto-1,2-propanediol, 2-mercaptoethanol, 1,2-ethanedithiol, 6-mercapto-1-hexanol, 1-octanethiol, 1-dodecanethiol, 10-hydroxy-1-dodecanethiol, 10-carboxy-1-dodecanethiol, 10-amino-1-dodecanethiol, sodium 1-dodecanethiolsulfonate, thiophenol, thiobenzoic acid, 4-aminothiophenol, p-toluenethiol, 2,4-dimethylbenzenethiol, 3-mercapto-1,2,4-triazole, and 2-mercaptobenzothiazole. Among these, 3-mercapto-1,2-propanediol is preferred from the standpoint of the water solubility and the waste treatment.

In the step of forming the release layer, the compound containing two or less mercapto groups in the molecule may be used in the form of an aqueous solution. For enhancing the solubility to water, an alcohol, such as methanol and ethanol, may be added. The addition of an alcohol is effective particularly in the case where the compound containing two or less mercapto groups in the molecule having high hydrophobicity is used.

When the concentration of the compound containing two or less mercapto groups in the molecule in the aqueous solution is large, there is a tendency that the release strength of the metal foil and the resin substrate is decreased, and the release strength can be controlled by controlling the concentration of the compound containing two or less mercapto groups in the molecule. The concentration of the compound containing two or less mercapto groups in the molecule in the aqueous solution is not limited, and may be from 0.01 to 10.0% by mass, and typically from 0.1 to 5.0% by mass.

The pH of the aqueous solution of the compound containing two or less mercapto groups in the molecule is not particularly limited, and the aqueous solution may be used as acidic or alkaline. For example, the aqueous solution may be used in a pH range of from 3.0 to 10.0. The pH is preferably around neutral in a range of from 5.0 to 9.0, and more preferably in a range of from 7.0 to 9.0, from the standpoint that any particular control of the pH is not necessary.

### (3) Metal Alkoxide

The release layer may be constituted by one kind or a combination of plural kinds of an aluminate compound, a titanate compound, or a zirconate compound represented by the following formula, a hydrolyzed product of the aluminate compound, the titanate compound, or the zirconate compound, and a condensed product of the hydrolyzed product (which may be hereinafter referred simply to a metal alkoxide). By adhering the metal foil and the resin substrate through the release layer, the adhesion can be appropriately decreased to control the release strength.

(R¹)ₘ-M-(R²)ₙ

In the formula, R¹ represents an alkoxy group or a halogen atom; R² represents a hydrocarbon group selected from the group consisting of an alkyl group, a cycloalkyl group, and an aryl group, or the hydrocarbon group, in which one or more hydrogen atom is substituted by a halogen atom; M represents any one of Al, Ti, and Zr; n represents 0, 1, or 2; and m represents an integer of 1 or more and a valency of M or less, provided that at least one of R¹ is an alkoxy group, and m+n is a valency of M, which is 3 for Al or 4 for Ti and Zr.

The metal alkoxide necessarily has at least one alkoxy group. In the case where no alkoxy group is present, and the substituents are constituted only by a hydrocarbon group selected from the group consisting of an alkyl group, a cycloalkyl group, and an aryl group, or the hydrocarbon group, in which one or more hydrogen atom is substituted by a halogen atom, there is a tendency that the adhesion of the resin substrate and the metal foil is excessively decreased. The metal alkoxide necessarily has from 0 to 2 of a hydrocarbon group selected from the group consisting of an alkyl group, a cycloalkyl group, and an aryl group, and the hydrocarbon group, in which one or more hydrogen atom is substituted by a halogen atom. In the case where the metal alkoxide has 3 or more of the hydrocarbon groups, there is a tendency that the adhesion of the resin substrate and the metal foil is excessively decreased. The alkoxy group herein encompasses an alkoxy group, in which one or more hydrogen atom is substituted by a halogen atom. For controlling the release strength of the resin substrate and the metal foil to the aforementioned range, the metal alkoxide preferably has two or more alkoxy groups and one or two of the hydrocarbon group (including the hydrocarbon group, in which one or more hydrogen atom is substituted by a halogen atom).

The alkyl group is not limited, and examples thereof include a linear or branched alkyl group having a number of carbon atoms of from 1 to 20, preferably a number of carbon atoms of from 1 to 10, and more preferably a number of carbon atoms of from 1 to 5, such as a methyl group, an ethyl group, a n- or iso-propyl group, a n-, iso-, or tert-butyl group, a n-, iso-, or neo-pentyl group, a n-hexyl group, a n-octyl group, and a n-decyl group.

The cycloalkyl group is not limited, and examples thereof include a cycloalkyl group having a number of carbon atoms of from 3 to 10, and preferably a number of carbon atoms of from 5 to 7, such as a cyclopropyl group, a cyclobutyl group, a cyclopentyl group, a cyclohexyl group, a cycloheptyl group, and a cyclooctyl group.

Examples of the aromatic hydrocarbon group that is preferred as R² include an aryl group having a number of carbon atoms of from 6 to 20, and preferably a number of carbon atoms of from 6 to 14, such as a phenyl group, a phenyl group substituted by an alkyl group (such as a tolyl group and a xylyl group), a 1- or 2-naphthyl group, and an anthryl group, and in the hydrocarbon group, one or more hydrogen atom may be substituted by a halogen atom, and for example, may be substituted by a fluorine atom, a chlorine atom, or a bromine atom.

Preferred examples of the aluminate compound include trimethoxyaluminum, methyldimethoxyaluminum, ethyldimethoxyaluminum, n- or iso-propyldimethoxyaluminum, n-, iso-, or tert-butyldimethoxyaluminum, n-, iso-, or neo-pentyldimethoxyaluminum, hexyldimethoxyaluminum, octyldimethoxyaluminum, decyldimethoxyaluminum, phenyldimethoxyaluminum, alkyl-substituted phenyldimethoxyaluminum (such as p-(methyl)phenyldimethoxyaluminum), dimethylmethoxyaluminum, triethoxyaluminum, methyldiethoxyaluminum, ethyldiethoxyaluminum, n- or iso-propyldiethoxyaluminum, n-, iso-, or tert-butyldiethoxyaluminum, pentyldiethoxyaluminum, hexyldiethoxyaluminum, octyldiethoxyaluminum, decyldiethoxyaluminum, phenyldiethoxyaluminum, alkyl-substituted phenyldiethoxyaluminum (such as p-(methyl)phenyldiethoxyaluminum), dimethylethoxyaluminum, triisopropoxyaluminum, methyldiisopropoxyaluminum, ethyldiisopropoxyaluminum, n- or iso-propyldiethoxyaluminum, n-, iso-, or tert-butyldiisopropoxyaluminum, pentyldiisopropoxyaluminum, hexyldiisopropoxyaluminum, octyldiisopropoxyaluminum, decyldiisopropoxyaluminum, phenyldiisopropoxyaluminum, alkyl-substituted phenyldiisopropoxyaluminum (such as p-(methyl)phenyldiisopropoxyaluminum), dimethylisopropoxyaluminum, (3,3,3-trifluoropropyl)dimethoxyaluminum, tridecafluorooctyldiethoxyaluminum, methyldichloroaluminum, dimethylchloroaluminum, dimethylchloroaluminum, phenyldichloroaluminum, dimethylfluoroaluminum, dimethylbromoaluminum, diphenylbromoaluminum, hydrolyzed products of the aluminate compounds, and condensed products of the hydrolyzed products. Among these, trimethoxyaluminum, triethoxyaluminum, and triisopropoxyaluminum are preferred from the standpoint of the availability.

Preferred examples of the titanate compound include tetramethoxytitanium, methyltrimethoxytitanium, ethyltrimethoxytitanium, n- or iso-propyltrimethoxytitanium, n-, iso-, or tert-butyltrimethoxytitanium, n-, iso-, or neo-pentyltrimethoxytitanium, hexyltrimethoxytitanium, octyltrimethoxytitanium, decyltrimethoxytitanium, phenyltrimethoxytitanium, alkyl-substituted phenyltrimethoxytitanium (such as p-(methyl)phenyltrimethoxytitanium), dimethyldimethoxytitanium, tetraethoxytitanium, methyltriethoxytitanium, ethyltriethoxytitanium, n- or iso-propyltriethoxytitanium, n-, iso-, or tert-butyltriethoxytitanium, pentyltriethoxytitanium, hexyltriethoxytitanium, octyltriethoxytitanium, decyltriethoxytitanium, phenyltriethoxytitanium, alkyl-substituted phenyltriethoxytitanium (such as p-(methyl)phenyltriethoxytitanium), dimethyldiethoxytitanium, tetraisopropoxytitanium, methyltriisopropoxytitanium, ethyltriisopropoxytitanium, n- or iso-propyltriethoxytitanium, n-, iso-, or tert-butyltriisopropoxytitanium, pentyltriisopropoxytitanium, hexyltriisopropoxytitanium, octyltriisopropoxytitanium, decyltriisopropoxytitanium, phenyltriisopropoxytitanium, alkyl-substituted phenyltriisopropoxytitanium (such as p-(methyl)phenyltriisopropoxytitanium), dimethyldiisopropoxytitanium, (3,3,3-trifluoropropyl)trimethoxytitanium, tridecafluorooctyltriethoxytitanium, methyltrichlorotitanium, dimethyldichlorotitanium, trimethylchlorotitanium, phenyltrichlorotitanium, dimethyldifluorotitanium, dimethyldibromotitanium, diphenyldibromotitanium, hydrolyzed products of the titanate compounds, and condensed products of the hydrolyzed products. Among these, tetramethoxytitanium, tetraethoxytitanium, and tetraisopropoxytitanium are preferred from the standpoint of the availability.

Preferred examples of the zirconate compound include tetramethoxyzirconium, methyltrimethoxyzirconium, ethyltrimethoxyzirconium, n- or iso-propyltrimethoxyzirconium, n-, iso-, or tert-butyltrimethoxyzirconium, n-, iso-, or neo-pentyltrimethoxyzirconium, hexyltrimethoxyzirconium, octyltrimethoxyzirconium, decyltrimethoxyzirconium, phenyltrimethoxyzirconium, alkyl-substituted phenyltrimethoxyzirconium (such as p-(methyl)phenyltrimethoxyzirconium), dimethyldimethoxyzirconium, tetraethoxyzirconium, methyltriethoxyzirconium, ethyltriethoxyzirconium, n- or iso-propyltriethoxyzirconium, n-, iso-, or tert-butyltriethoxyzirconium, pentyltriethoxyzirconium, hexyltriethoxyzirconium, octyltriethoxyzirconium, decyltriethoxyzirconium, phenyltriethoxyzirconium, alkyl-substituted phenyltriethoxyzirconium (such as p-(methyl)phenyltriethoxyzirconium), dimethyldiethoxyzirconium, tetraisopropoxyzirconium, methyltriisopropoxyzirconium, ethyltriisopropoxyzirconium, n- or iso-propyltriethoxyzirconium, n-, iso-, or tert-butyltriisopropoxyzirconium, pentyltriisopropoxyzirconium, hexyltriisopropoxyzirconium, octyltriisopropoxyzirconium, decyltriisopropoxyzirconium, phenyltriisopropoxyzirconium, alkyl-substituted phenyltriisopropoxyzirconium (such as p-(methyl)phenyltriisopropoxytitanium), dimethyldiisopropoxyzirconium, (3,3,3-trifluoropropyl)trimethoxyzirconium, tridecafluorooctyltriethoxyzirconium, methyltrichlorozirconium, dimethyldichlorozirconium, trimethylchlorozirconium, phenyltrichlorozirconium, dimethyldifluorozirconium, dimethyldibromozirconium, diphenyldibromozirconium, hydrolyzed products of the zirconate compounds, and condensed products of the hydrolyzed products. Among these, tetramethoxyzirconium, tetraethoxyzirconium, and tetraisopropoxyzirconium are preferred from the standpoint of the availability.

In the step of forming the release layer, the metal alkoxide may be used in the form of an aqueous solution. For enhancing the solubility to water, an alcohol, such as methanol and ethanol, may be added. The addition of an alcohol is effective particularly in the case where the metal alkoxide having high hydrophobicity is used.

When the concentration of the metal alkoxide in the aqueous solution is large, there is a tendency that the release strength of the metal foil and the resin substrate is decreased, and the release strength can be controlled by controlling the concentration of the metal alkoxide. The concentration of the metal alkoxide in the aqueous solution is not limited, and may be from 0.001 to 1.0 mol/L, and typically from 0.005 to 0.2 mol/L.

The pH of the aqueous solution of the metal alkoxide is not particularly limited, and the aqueous solution may be used as acidic or alkaline. For example, the aqueous solution may be used in a pH range of from 3.0 to 10.0. The pH is preferably around neutral in a range of from 5.0 to 9.0, and more preferably in a range of from 7.0 to 9.0, from the standpoint that any particular control of the pH is not necessary.

### (4) Others

Known substance having release property, such as a silicone release agent and a resin film having release property, may be used in the release layer.

The metal foil according to the invention may have one or more layer selected from the group consisting of a roughening treatment layer, a heat resistant layer, a rust preventing layer, a chromate treatment layer, and a silane coupling treatment layer, between the metal foil and the release layer. The chromate treatment layer herein means a layer treated with a liquid containing chromic anhydride, chromic acid, dichromic acid, chromate (salt), a dichromate (salt). The chromate treatment layer may contain an element, such as cobalt, iron, nickel, molybdenum, zinc, tantalum, copper, aluminum, phosphorus, tungsten, tin, arsenic, titanium, or the like (which may be in any form of a metal, an alloy, an oxide, a nitride, a sulfide, and the like). Specific examples of the chromate treatment layer include a chromate treatment layer that is treated with an aqueous solution of chromic anhydride or potassium dichromate, and a chromate treatment layer that is treated with a treatment liquid containing chromic anhydride or potassium dichromate and zinc.

The roughening treatment layer may be formed, for example, by the following treatment.

### Spherical Roughening

Spherical roughening particles are formed by using a copper roughening plating bath containing Cu, H₂SO₄, and As shown below.

### Liquid Composition 1

CuSO₄.5H₂O: 78 to 196 g/L

Cu: 20 to 50 g/L

H₂OS₄: 50 to 200 g/L

Arsenic: 0.7 to 3.0 g/L

### Electroplating Temperature 1

30 to 76° C.

### Electric Current Condition 1

Electric current density: 35 to 105 A/dm² (critical current density of the bath or more)

### Plating Time 1

1 to 240 seconds

Subsequently, for preventing the dropout of the roughening particles and enhancing the peel strength thereof, overlay plating is formed with a copper electrolytic bath containing sulfuric acid and copper sulfate. The overlay plating condition is shown below.

### Liquid Composition 2

CuSO₄.5H2O: 88 to 352 g/L

Cu: 22 to 90 g/L

H₂OS₄: 50 to 200 g/L

### Electroplating Temperature 2

25 to 80° C.

### Electric Current Condition 2

Electric current density: 15 to 32 A/dm² (less than the critical current density of the bath)

### Plating Time 1

1 to 240 seconds

The heat resistant layer and the rust preventing layer used may be a known heat resistant layer and a known rust preventing layer respectively. For example, the heat resistant layer and/or the rust preventing layer may be a layer containing one or more element selected from the group consisting of nickel, zinc, tin, cobalt, molybdenum, copper, tungsten, phosphorus, arsenic, chromium, vanadium, titanium, aluminum, gold, silver, a platinum group element, iron, and tantalum, and may also be a metal layer or an alloy layer formed of one or more element selected from the group consisting of nickel, zinc, tin, cobalt, molybdenum, copper, tungsten, phosphorus, arsenic, chromium, vanadium, titanium, aluminum, gold, silver, a platinum group element, iron, and tantalum. The heat resistant layer and/or the rust preventing layer may contain an oxide, a nitride, and a silicide containing one or more element selected from the group consisting of nickel, zinc, tin, cobalt, molybdenum, copper, tungsten, phosphorus, arsenic, chromium, vanadium, titanium, aluminum, gold, silver, a platinum group element, iron, and tantalum. The heat resistant layer and/or the rust preventing layer may be a layer containing a nickel-zinc alloy. The heat resistant layer and/or the rust preventing layer may be a nickel-zinc alloy layer. The nickel-zinc alloy layer may contain from 50 to 99% by weight of nickel and from 50 to 1% by weight of zinc except for unavoidable impurities. The total coating amount of zinc and nickel of the nickel-zinc alloy layer may be from 5 to 1,000 mg/m², preferably from 10 to 500 mg/m², and more preferably from 20 to 100 mg/m². The ratio of the coating amount of nickel to the coating amount of zinc (=(coating amount of nickel)/(coating amount of zinc)) of the layer containing a nickel-zinc alloy or the nickel-zinc alloy layer is preferably from 1.5 to 10. The coating amount of nickel of the layer containing a nickel-zinc alloy or the nickel-zinc alloy layer is preferably from 0.5 mg/m² to 500 mg/m², and more preferably from 1 mg/m² to 50 mg/m².

For example, the heat resistant layer and/or the rust preventing layer may be a layer containing a nickel or nickel alloy layer having a coating amount of from 1 mg/m² to 100 mg/m², preferably from 5 mg/m² to 50 mg/m², and a tin layer having a coating amount of from 1 mg/m² to 80 mg/m², preferably from 5 mg/m² to 40 mg/m², which are laminated sequentially, and the nickel alloy layer may be constituted by any one of nickel-molybdenum, nickel-zinc, and nickel-molybdenum-cobalt. The heat resistant layer and/or the rust preventing layer preferably has a total coating amount of nickel or a nickel alloy and tin of from 2 mg/m² to 150 mg/m², and more preferably from 10 mg/m² to 70 mg/m². The heat resistant layer and/or the rust preventing layer preferably has a ratio (nickel coating amount in nickel or a nickel alloy)/(tin coating amount) of from 0.25 to 10, and more preferably from 0.33 to 3.

The silane coupling agent used in the silane coupling treatment may be a known silane coupling agent, and for example, may be an amino silane coupling agent, an epoxy silane coupling agent, or a mercapto silane coupling agent. The silane coupling agent used may be vinyltrimethoxysilane, vinylphenyltrimethoxysilane, γ-methacryloxypropyltrimethoxysilane, γ-glycidoxypropyltrimethoxysilane, 4-glycidylbutyltrimethoxysilane, γ-aminopropyltriethoxysilane, N-β-(aminoethyl)-γ-aminopropyltrimethoxysilane, N-3-(4-(3-aminopropoxy)butoxy)propyl-3-aminopropyltrimethoxysilane, imidazolesilane, triazinesilane, γ-mercaptopropyltrimethoxysilane, or the like.

The silane coupling treatment layer may be formed by using a silane coupling agent, such as an epoxy silane, an amino silane, a methacryloxy silane, and a mercapto silane. The silane coupling agent may be used as a mixture of two or more kinds thereof. Among these, a layer formed by using an amino silane coupling agent or an epoxy silane coupling agent is preferred.

The amino silane coupling agent referred herein may be selected from the group consisting of N-(2-aminoethyl)-3-aminopropyltrimethoxysilane, 3-(N-styrylmethyl-2-aminoethylamino)propyltrimethoxysilane, 3-aminopropyltriethoxysilane, bis(2-hydroxyethyl)-3-aminopropyltriethoxysilane, aminopropyltrimethoxysilane, N-methylaminopropyltrimethoxysilane, N-phenylaminopropyltrimethoxysilane, N-(3-acryloxy-2-hydroxypropyl)-3-aminopropyltriethoxysilane, 4-aminobutyltriethoxysilane, (ami noethylaminomethyl)phenethyltrimethoxysilane, N-(2-aminoethyl-3-aminopropyl)trimethoxysilane, N-(2-aminoethyl-3-aminopropy)tris(2-ethylhexyloxy)silane, 6-(aminohexylaminopropyl)trimethoxysilane, aminophenyltrimethoxysilane, 3-(1-aminopropoxy)-3,3-dimethyl-1-propenyltrimethoxysilane, 3-aminopropyltris(methoxyethoxyethoxy)silane, 3-aminopropyltriethoxysilane, 3-aminopropyltrimethoxysilane, ω-aminoundecyltrimethoxysilane, 3-(2-N-benzylaminoethylaminopropyl)trimethoxysilane, bis(2-hydroxyethyl)-3-aminopropyltriethoxysilane, (N,N-diethyl-3-aminopropyl)trimethoxysilane, (N,N-dimethyl-3-aminopropyl)trimethoxysilane, N-methylaminopropyltrimethoxysilane, N-phenylaminopropyltrimethoxysilane, 3-(N-styrylmethyl-2-aminoethylamino)propyltrimethoxysilane, γ-aminopropyltriethoxysilane, N-β-(aminoethyl)-γ-aminopropyltrimethoxysilane, and N-3-(4-(3-aminopropoxy)butoxy)propyl-3-aminopropyltrimethoxysilane.

The silane coupling treatment layer is preferably provided in terms of silicon atom in a range of from 0.05 mg/m² to 200 mg/m², more preferably from 0.15 mg/m² to 20 mg/m², and further preferably from 0.3 mg/m² to 2.0 mg/m². The silane coupling treatment layer within the aforementioned range may enhance the adhesion between the resin substrate and the metal foil.

The surface treatments described in WO 2008/053878, JP-A-2008-111169, Japanese Patent No. 5,024,930, WO 2006/028207, Japanese Patent No. 4,828,427, WO 2006/134868, Japanese Patent No. 5,046,927, WO 2007/105635, Japanese Patent No. 5,180,815, and JP-A-2013-19056 may be applied to the surface of the metal foil, the roughening particle layer, the heat resistant layer, the rust preventing layer, the silane coupling treatment layer, the chromate treatment layer, or the release layer. Accordingly, the metal foil of the invention encompasses a surface treated metal foil.

A resin layer may be provided on the metal foil of the invention on the side having the surface unevenness, or on the metal foil having a release layer on the side of the release layer.

The resin layer on the surface of the metal foil may be an adhesive resin, i.e., an adhesive, may be a primer, and may be an insulating resin layer in a semi-cured state for adhesion (i.e., in a B stage). The semi-cured state (B stage) include such a state that the surface thereof has no tackiness on touching with a finger, the insulating resin layers can be stacked and stored, and the insulating resin layer undergoes curing reaction on subjecting to a heat treatment. The resin layer on the surface of the metal foil is preferably a resin layer that exhibits an appropriate release strength (for example, from 2 gf/cm to 200 gf/cm) in the case where the resin layer is in contact with the release layer. In the resin layer, such a resin is preferably used that follows the unevenness on the surface of the metal foil, so as to prevent gaps and bubbles capable of causing blister from being entrained. For example, the resin layer is preferably provided by using a resin having a low viscosity, such as a viscosity of the resin of 10,000 mPa·s (25° C.) or less, and more preferably 5,000 mPa·s (25° C.) or less, on providing the resin layer on the surface of the metal foil. By providing the resin layer between the metal foil and the insulating substrate laminated on the metal foil, the resin layer may follow the surface of the metal foil even in the case where the insulating substrate that is hard to follow the unevenness on the surface of the metal foil, and thereby it is effective that gaps and bubbles can be prevented from being formed between the metal foil and the insulating substrate.

The resin layer on the surface of the metal foil may contain a thermosetting resin, and may be a thermosetting resin. The resin layer on the surface of the metal foil may contain a thermoplastic resin. The resin layer on the surface of the metal foil may contain a resin, a resin curing agent, a compound, a curing accelerator, a dielectric material, a reaction catalyst, a crosslinking agent, a polymer, a prepreg, an aggregate, and the like, which have been known. The resin layer on the surface of the metal foil may contain the substances (such as a resin, a resin curing agent, a compound, a curing accelerator, a dielectric material, a reaction catalyst, a crosslinking agent, a polymer, a prepreg, an aggregate, and the like) and/or may be formed by the forming methods and the forming equipments, described in WO 2008/004399, WO 2008/053878, WO 2009/084533, JP-A-11-5828, JP-A-11-140281, Japanese Patent No. 3,184,485, WO 97/02728, Japanese Patent No. 3,676,375, JP-A-2000-43188, Japanese Patent No. 3,612,594, JP-A-2002-179772, JP-A-2002-359444, JP-A-2003-304068, Japanese Patent No. 3,992,225, JP-A-2003-249739, Japanese Patent No. 4,136,509, JP-A-2004-82687, Japanese Patent No. 4,025,177, JP-A-2004-349654, Japanese Patent No. 4,286,060, JP-A-2005-262506, Japanese Patent No. 4,570,070, JP-A-2005-53218, Japanese Patent No. 3,949,676, Japanese Patent No. 4,178,415, WO 2004/005588, JP-A-2006-257153, JP-A-2007-326923, JP-A-2008-111169, Japanese Patent No. 5,024,930, WO 2006/028207, Japanese Patent No. 4,828,427, JP-A-2009-67029, WO 2006/134868, Japanese Patent No. 5,046,927, JP-A-2009-173017, WO 2007/105635, Japanese Patent No. 5,180,815, WO 2008/114858, WO 2009/008471, JP-A-2011-14727, WO 2009/001850, WO 2009/145179, WO 2011/068157, JP-A-2013-19056.

### Laminated Material, Semiconductor Package, and Electronic Device

A laminated material can be produced by providing a resin substrate on the metal foil according to the invention on the side having the surface profile, or on the metal foil having a release layer according to the invention on the side of the release layer. In the laminated material, the resin substrate may be formed with a paper substrate phenol resin, a paper substrate epoxy resin, a synthetic fiber cloth substrate epoxy resin, a glass fiber cloth-paper composite substrate epoxy resin, a glass fiber cloth-glass nonwoven cloth composite substrate epoxy resin, a glass fiber cloth substrate epoxy resin, or the like. The resin substrate may be a prepreg, or may contain a thermosetting resin. A printed wiring board can be produced by forming a circuit on the metal foil of the laminated material. Furthermore, a printed circuit board can be produced by mounting an electronic component or the like on the printed wiring board. In the invention, the “printed wiring board” encompasses a printed wiring board, a printed circuit board, and a printed board, which each have an electronic component or the like mounted thereon. An electronic device may be produced by using the printed wiring board, an electronic device may be produced by using the printed wiring board, which has an electronic component or the like mounted thereon, and an electronic device may be produced by using the printed board, which has an electronic component or the like mounted thereon. The “printed circuit board” encompasses a circuit board for a semiconductor package. A semiconductor package can be produced by mounting an electronic component or the like on the circuit board for a semiconductor package.

### Method for Producing Printed Wiring Board

The method for producing a printed wiring board of the invention in one aspect contains: adhering a resin substrate to the metal foil of the invention on the side having the surface profile or the metal foil having a release layer of the invention on the side of the release layer; releasing the metal foil or the metal foil having a release layer without etching, from the resin substrate, so as to provide a resin substrate having the surface profile of the metal foil or the metal foil having a release layer, transferred to the released surface of the resin substrate; and forming a circuit on the released surface of the resin substrate having the surface profile transferred. According to the constitution, while providing or not providing the release layer on the metal foil, the physical release of the resin substrate, to which the metal foil is adhered, is enabled, and in the step of removing the metal foil from the resin substrate, the metal foil can be removed with good cost without damaging the surface profile of the metal foil transferred to the surface of the resin substrate. In the production method, the circuit may be formed with a plated pattern. In this case, after forming a plated pattern, a target circuit may be formed by utilizing the plated pattern, so as to produce the printed wiring board. The circuit may also be formed with a printed pattern. In this case, after forming a printed patter, for example, with ink-jet containing a conductive paste or the like in an ink, a target circuit may be formed by utilizing the printed pattern, so as to produce the printed wiring board.

In the description herein, the “surface profile” means an unevenness shape on a surface.

The method for producing a printed wiring board of the invention in another aspect contains: adhering a resin substrate to the metal foil of the invention on the side of the surface controlled for Sq or Sq/Rms of the surface or on the side of the release layer; releasing the metal foil or the metal foil having a release layer without etching, from the resin substrate, so as to provide a resin substrate having a surface profile of the metal foil, transferred to a released surface of the resin substrate; and providing a build-up layer on the released surface of the resin substrate having the surface profile transferred. According to the constitution, while providing or not providing the release layer on the metal foil, the physical release of the resin substrate, to which the metal foil is adhered, is enabled, and in the step of removing the metal foil from the resin substrate, the metal foil can be removed with good cost without damaging the surface profile of the metal foil transferred to the surface of the resin substrate. Furthermore, with the prescribed surface unevenness transferred to the resin substrate, the resin substrate and the build-up layer can be adhered with good adhesion in the case where the resin component of the resin substrate and the resin component of the build-up layer are different from each other or the same as each other.

The “build-up layer” herein means a layer that has a conductive layer, a wiring pattern or a circuit, and an insulator, such as a resin. The shape of the insulator, such as a resin, may be in the form of a layer. A conductive layer, a wiring pattern or a circuit, and an insulator, such as a resin, may be provided in any manner.

The build-up layer may be produced by providing a conductive layer, a wiring pattern or a circuit, and an insulator, such as a resin, on the resin substrate on the side of the released surface having the surface profile of the metal foil transferred to the released surface. The method for forming the conductive layer, the wiring pattern or the circuit, and the insulator, such as a resin, may be a known method, such as a semi-additive process, a full additive process, a subtractive process, and a partly additive process.

The build-up layer may have plural layers, and may have plural conductive layers, wiring patterns or circuits, and resin (layers).

The plural conductive layers and wiring patterns or circuits may be electrically insulated with the insulator, such as a resin. The plural conductive layers and wiring patterns or circuits that are electrically insulated may be electrically connected by forming a through hole and/or a blind via in the insulator, such as a resin, with laser and/or a drill, and then forming conductive plating, such as copper plating, in the through hole and/or the blind via.

A printed wiring board may be produced in such a manner that the metal foils that have the controlled Sq or Sq/Rms or the metal foils having a release layer are adhered to the both surfaces of the resin substrate from the side having the controlled Sq or Sq/Rms or the side of the release layer, then the metal foils or the metal foils having a release layer are removed, so as to transfer the surface profile of the metal foil to the both surfaces of the resin substrate, and circuits, wiring patterns, or build-up layers are formed on the both surfaces of the resin substrate.

The insulator constituting the build-up layer may be the resins, the resin layers, and the resin substrates described herein, and a resin, a resin layer, an insulator, a prepreg, a substrate obtained by impregnating a glass cloth with a resin, and the like, which have been known, may be used. The resin may contain an inorganic material and/or an organic material. The resin constituting the build-up layer may be formed with a material having a low specific permeability, such as an LCP (liquid crystal polymer) and polytetrafluoroethylene. Associated with the spread of high-frequency equipment in recent years, such a movement is becoming active that a material having a low specific permeability, such as an LCP (liquid crystal polymer) and polytetrafluoroethylene (Teflon, a trade name), is incorporated to a structure of a printed board. At this time, these materials are thermoplastic, and thus unavoidably undergo a shape change on hot pressing, and there is a basic issue in mass production that the production yield cannot be increased with the substrate structure containing only the LCP (liquid crystal polymer) or polytetrafluoroethylene. In the production method of the invention described above, as a solution to the issue, a printed wiring board that is excellent in high frequency characteristics and can be prevented from undergoing a shape change on applying heat can be provided by using a thermosetting resin, such as an epoxy resin, as the resin substrate, and adhering the resin substrate.

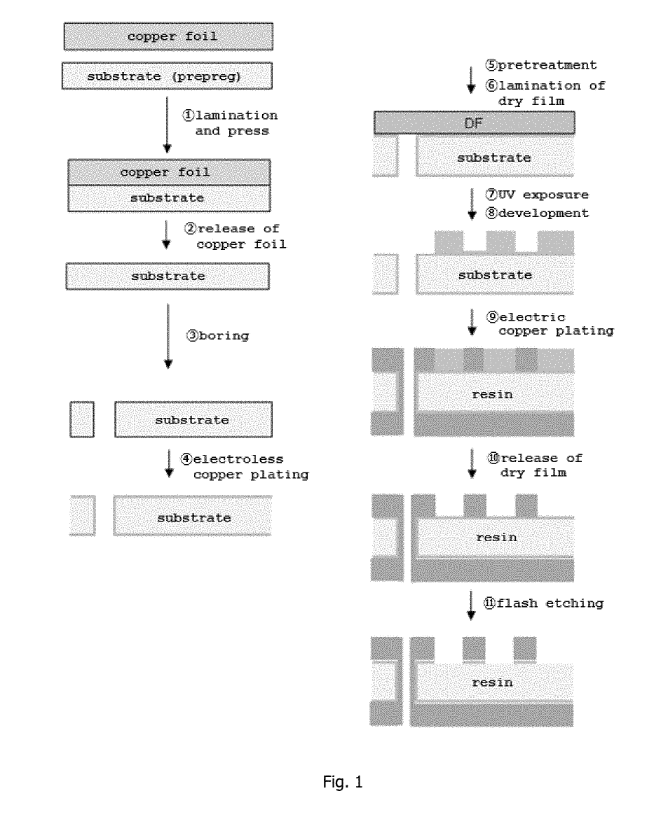

A fine circuit can be formed by a semi-additive process by using the metal foil of the invention. FIG. 1 is a schematic example of a semi-additive process using the surface profile of the metal foil. The semi-additive process uses the surface profile of the metal foil. Specifically, the metal foil having a release layer of the invention is laminated on a resin substrate from the side of the release layer to produce a laminated material. The metal foil of the laminated material is then removed by etching, or released. The surface of the resin substrate having the surface profile of the metal foil transferred thereto is cleaned with diluted sulfuric acid or the like, and then subjected to electroless copper plating. The portion of the resin substrate, on which the circuit is not to be formed, is covered with a dry film or the like, and then the surface of the electroless copper plated layer that is not covered with the dry film is subjected to electric (electrolytic) copper plating. Thereafter, the dry film is removed, and then the electroless copper plated layer formed on the portion, on which the circuit is not to be formed, is removed, so as to form a fine circuit. The fine circuit formed in the invention is adhered to the released surface of the resin substrate having the surface profile of the metal foil of the invention transferred thereto, and thus has a good adhesion force (i.e., a good peel strength).

Another embodiment of the semi-additive process is as follows.

The semi-additive process means such a method that thin electroless plating is formed on a resin substrate or a metal foil, a pattern is formed, and then a conductor pattern is formed by electric plating and etching. Accordingly, one embodiment of the method for producing a printed wiring board according to the invention by the semi-additive process contains:

preparing a metal foil according to the invention or a metal foil having a release layer according to the invention and a resin substrate:

laminating the resin substrate on the metal foil or the metal foil having a release layer on the side having a controlled surface profile or on the side having the release layer;

after laminating the metal foil and the resin substrate, removing the metal foil by etching, or releasing the metal foil;

providing a through hole and/or a blind via on an exposed surface or a released surface of the resin substrate formed by removing or releasing the metal foil;

subjecting a region containing the through hole and/or the blind via to a desmear treatment;

cleaning the resin substrate and the region containing the through hole and/or the blind via with diluted sulfuric acid or the like, and prividing an electroless plated layer (such as an electroless copper plated layer) thereon;

providing a plating resist on the electroless plated layer;

exposing the plating resist, and then removing the plating resist in a region, in which a circuit is to be formed;

providing an electrolytic plated layer (such as an electrolytic copper plated layer) on the region, in which a circuit is to be formed, and from which the plating resist is removed;

removing the plating resist; and

removing the electroless plated layer on a region except for the region, in which a circuit is formed, by flash etching or the like.

Another embodiment of the method for producing a printed wiring board according to the invention by the semi-additive process contains:

preparing a metal foil according to the invention or a metal foil having a release layer according to the invention and a resin substrate:

laminating the resin substrate on the metal foil or the metal foil having a release layer on the side having a controlled surface profile or on the side having the release layer;

after laminating the metal foil and the resin substrate, removing the metal foil by etching, or releasing the metal foil;

cleaning the surface of the resin substrate for an exposed surface or a released surface of the resin substrate formed by removing or releasing the metal foil with diluted sulfuric acid or the like, and prividing an electroless plated layer (such as an electroless copper plated layer) thereon;

providing a plating resist on the electroless plated layer;

exposing the plating resist, and then removing the plating resist in a region, in which a circuit is to be formed;

providing an electrolytic plated layer (such as an electrolytic copper plated layer) on the region, in which a circuit is to be formed, and from which the plating resist is removed;

removing the plating resist; and

removing the electroless plated layer on a region except for the region, in which a circuit is formed, by flash etching or the like.

According to the manners, a circuit can be formed on the released surface of the resin substrate after releasing the metal foil, and a circuit board for a semiconductor package can be produced. Furthermore, a printed wiring board and a semiconductor package can be produced by using the circuit board. Moreover, an electronic device can be produced by using the printed wiring board or the semiconductor package.

Another embodiment of the method for producing a printed wiring board according to the invention by the full additive process contains:

laminating the resin substrate on the metal foil or the metal foil having a release layer on the side having a controlled surface profile or on the side having the release layer:

laminating the resin substrate on the metal foil or the metal foil having a release layer on the side having a controlled surface profile or on the side having the release layer;

after laminating the metal foil and the resin substrate, removing the metal foil by etching, or releasing the metal foil;

cleaning an exposed surface or a released surface of the resin substrate formed by removing or releasing the metal foil with diluted sulfuric acid or the like;

providing a plating resist on the electroless plated layer;

exposing the plating resist, and then removing the plating resist in a region, in which a circuit is to be formed;

prividing an electroless plated layer (which may be, for example, an electroless copper plated layer or a thick electroless plated layer) in the region, in which a circuit is to be formed;

removing the plating resist.

In the semi-additive process and the full additive process, such an effect may be obtained in some cases that the electroless plated layer can be easily provided by cleaning the surface of the resin substrate. In the case where the release layer remains on the surface of the resin substrate, in particular, the release layer is partially or entirely removed from the surface of the resin substrate by the cleaning, and such an effect may be obtained in some cases that the electroless plated layer can be further easily provided by cleaning the surface of the resin substrate. The cleaning performed may be cleaning by known cleaning methods (including the kind and the temperature of the liquid used, the coating method of the liquid, and the like). A cleaning method that is capable of partially or entirely removing the release layer of the invention is preferably used.

According to the manners, by the semi-additive process or the full additive process, a circuit can be formed on the exposed surface or the released surface of the resin substrate after removing or releasing the metal foil, and a printed circuit board and a circuit board for a semiconductor package can be produced. Furthermore, a printed wiring board and a semiconductor package can be produced by using the circuit board. Moreover, an electronic device can be produced by using the printed wiring board or the semiconductor package.

In the case where the measurement of the surface of the metal foil with an equipment, such as a scanning electron microscope having XPS (X-ray photoelectron spectrometer), EPMA (electron probe microanalyzer), or EDX (energy dispersive X-ray spectrometer) reveals that Si is detected, it can be estimated that a silane compound is present on the surface of the metal foil. Furthermore, in the case where the peel strength (release strength) of the metal foil and the resin substrate is 200 gf/cm or less, it can be estimated that the aforementioned silane compound capable of being used in the release layer according to the invention is used.

In the case where the measurement of the surface of the metal foil with an equipment, such as a scanning electron microscope having XPS (X-ray photoelectron spectrometer), EPMA (electron probe microanalyzer), or EDX (energy dispersive X-ray spectrometer) reveals that S is detected, and the peel strength (release strength) of the metal foil and the resin substrate is 200 gf/cm or less, it can be estimated that the aforementioned compound containing two or less mercapto groups in the molecule capable of being used in the release layer according to the invention is present on the surface of the metal foil.

In the case where the measurement of the surface of the metal foil with an equipment, such as a scanning electron microscope having XPS (X-ray photoelectron spectrometer), EPMA (electron probe microanalyzer), or EDX (energy dispersive X-ray spectrometer) reveals that Al, Ti, or Zr is detected, and the peel strength (release strength) of the metal foil and the resin substrate is 200 gf/cm or less, it can be estimated that the aforementioned metal alkoxide capable of being used in the release layer according to the invention is present on the surface of the metal foil.

### EXAMPLES

Experimental examples as invention examples and comparative examples will be shown below. The invention examples are provided for facilitating a greater understanding of the invention and the advantages thereof, and do not intend to limit the invention.

### Production of Raw Foil (Copper Foil Before Surface Treatment)

In Examples 1 to 10 and 12 and Comparative Example 2, electrolytic raw foils having the thickness shown in Table 1 were produced.

### Composition of Electrolytic Solution

Cu: 120 g/L

H₂SO₄: 100 g/L

Chloride ion (Cl⁻): 70 ppm

Fish glue: 6 ppm

Temperature of electrolytic solution: 60° C.

The electric current density and the linear velocity of the electrolytic solution are shown in Table 1.

In Example 11 and Comparative Example 1, 80 ppm of bis(3-sulfopropyl)disulfide (SPS) was added as an additive to the aforementioned electrolytic solution.

In Example 13, the same composition of the electrolytic solution as in Examples 1 to 10 and 12 and Comparative Example 2 except that the chloride ion concentration was 2 ppm or less, and 2 ppm of animal glue was added instead of the fish glue.

### Surface Treatment

As a surface treatment, the M surface (matte surface) of the raw foil was subjected to any one or a combination of a roughening treatment, a barrier treatment (heat resistant treatment), a rust preventing treatment, a silane coupling treatment, and a resin layer forming treatment, under the following conditions. Subsequently, a release layer was formed under the following condition on the copper foil on the side having been treated. The treatments were performed in the described order unless otherwise indicated. In Table 1, the term “no” for the treatment means that the treatment was not performed.

### (1) Roughening Treatment

### Spherical Roughening

Spherical roughening particles were formed by using a copper roughening plating bath containing Cu, H₂SO₄, and As shown below.

### Liquid Composition 1

CuSO₄.5H₂O: 78 to 118 g/L

Cu: 20 to 30 g/L

H₂SO₄: 12 g/L

Arsenic: 1.0 to 3.0 g/L

### Electroplating Temperature 1

25 to 33° C.

### Electric Current Condition 1

Electric current density: 78 A/dm² (critical current density of the bath or more)

### Plating Time 1

1 to 45 seconds

Subsequently, for preventing the dropout of the roughening particles and enhancing the peel strength thereof, overlay plating was formed with a copper electrolytic bath containing sulfuric acid and copper sulfate. The overlay plating condition is shown below.

### Liquid Composition 2

CuSO₄.5H₂O: 156 g/L

Cu: 40 g/L

H₂SO₄: 120 g/L

### Electroplating Temperature 2

40° C.

### Electric Current Condition 2

Electric current density: 20 A/dm² (less than the critical current density of the bath)

### Plating Time 2

1 to 60 seconds

### (2) Barrier Treatment (Heat Resistant Treatment)

### Liquid Composition

Ni: 13 g/L

Zn: 5 g/L

pH: 2

### Electric Plating Condition

Temperature: 40° C.

Electric current density: 8 A/dm²

### (3) Rust Preventing Treatment

### Liquid Composition

CrO₃: 2.5 g/L

Zn: 0.7 g/L

Na₂SO₄: 10 g/L

pH: 4.8

### Zinc Chromate Condition

Temperature: 54° C.

Electric current density: 0.7 A/dm²

### (4) Silane Coupling Treatment

### Liquid Composition

Tetraethoxysilane content: 0.4%

pH: 7.5

Coating method: spraying of solution

### (5) Formation of Release Layer

### Release Layer A

An aqueous solution of a silane compound (n-propyltrimethoxysilane, 4% by weight) was coated on the treated surface of the copper foil with a spray coater, and the surface of the copper foil was dried in the air at 100° C. for 5 minutes to form a release layer A. The agitation time from the dissolution of the silane compound in water to the coating was 30 hours, the alcohol concentration in the aqueous solution was 10% by volume, and the pH of the aqueous solution was from 3.8 to 4.2.

### Release Layer B

Sodium 1-dodecanethiolsulfomate was used as the compound containing two or less mercapto groups in the molecule, and an aqueous solution of sodium 1-dodecanethiolsulfomate (sodium 1-dodecanethiolsulfomate concentration: 3% by weight) was coated on the treated surface of the copper foil with a spray coater, and then dried in the air at 100° C. for 5 minutes to form a release layer B. The pH of the aqueous solution was from 5 to 9.

### Release Layer C

Triisopropoxyaluminum as an aluminate compound was used as the metal alkoxide, and an aqueous solution of triisopropoxyaluminum (triisopropoxyaluminum concentration: 0.04 mol/L) was coated on the treated surface of the copper foil with a spray coater, and then dried in the air at 100° C. for 5 minutes to form a release layer C. The agitation time from the dissolution of the aluminate compound in water to the coating was 2 hours, the alcohol concentration in the aqueous solution was 0% by volume, and the pH of the aqueous solution was from 5 to 9.

### Release Layer D

n-Decyltriisopropoxytitanium as a titanate compound was used as the metal alkoxide, and an aqueous solution of n-decyltriisopropoxytitanium (n-decyltriisopropoxytitanium concentration: 0.01 mol/L) was coated on the treated surface of the copper foil with a spray coater, and then dried in the air at 100° C. for 5 minutes to form a release layer D. The agitation time from the dissolution of the titanate compound in water to the coating was 24 hours, the alcohol concentration in the aqueous solution was 20% by volume of methanol, and the pH of the aqueous solution was from 5 to 9.

### Release Layer E

n-Propyl-tri-n-butoxyzirconium as a zirconate compound was used as the metal alkoxide, and an aqueous solution of n-propyl-tri-n-butoxyzirconium (n-propyl-tri-n-butoxyzirconium concentration: 0.04 mol/L) was coated on the treated surface of the copper foil with a spray coater, and then dried in the air at 100° C. for 5 minutes to form a release layer E. The agitation time from the dissolution of the titanate compound in water to the coating was 12 hours, the alcohol concentration in the aqueous solution was 0% by volume of methanol, and the pH of the aqueous solution was from 5 to 9.

(6) Resin Layer forming Treatment

In Example 1, after forming the release layer, a resin layer was further formed under the following condition.

### Resin Synthesis Example

In a 2-L three-neck flask equipped with a stainless steel anchor agitator, a nitrogen introducing tube, and an Allihn condenser attached above a trap with a stopper, 117.68 g (400 mmol) of 3,4,3′,4′-biphenyltetracarboxylic dianhydride, 87.7 g (300 mmol) of 1,3-bis(3-aminophenoxy)benzene, 4.0 g (40 mmol) of γ-valerolactone, 4.8 g (60 mmol) of pyridine, 300 g of N-methyl-2-pyrrolidone (hereinafter referred to as NMP), and 20 g of toluene were placed, heated to 180° C. for 1 hour, and then cooled to around room temperature, and then 29.42 g (100 mmol) of 3,4,3′,4′-biphenyltetracarboxylic dianhydride, 82.12 g (200 mmol) of 2,2-bis{4-(4-aminophenoxy)phenyl}propane, 200 g of NMP, and 40 g of toluene were added thereto, mixed at room temperature for 1 hour, and then heated to 180° C. for 3 hours, thereby providing a block copolymer polyimide having a solid content of 38%. The block copolymer polyimide had a ratio (general formula (1))/(general formula (2)) shown below of 3/2, a number average molecular weight of 70,000, and a weight average molecular weight of 150,000.

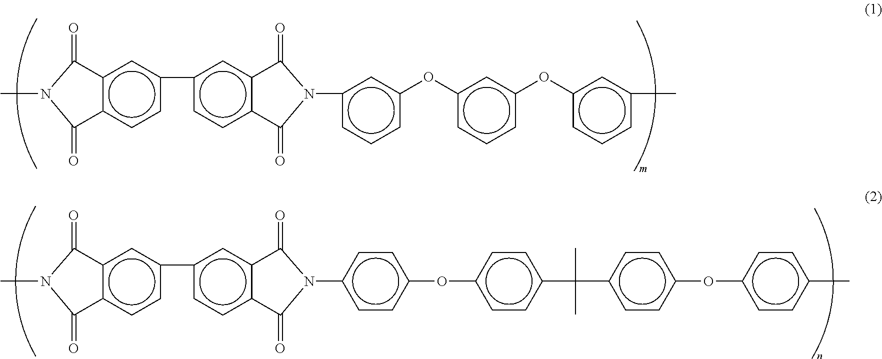

The resulting block copolymer polyimide solution obtained in Synthesis Example was further diluted with NMP to provide a block copolymer polyimide solution having a solid content of 10%. A resin solution was prepared with the block copolymer polyimide solution by mixing and dissolving bis(4-maleimidophenyl)methane (BMI-H, produced by K-I Chemical Industry Co., Ltd.) in a solid content weigh ratio of 35 and the block copolymer polyimide in a solid content weigh ratio of 65 (i.e., the ratio of (solid weight of bis(4-maleimidophenyl)methane contained in the resin solution)/(solid weight of the block copolymer polyimide contained in the resin solution) was 35/65) at 60° C. for 20 minutes. Thereafter, the resin solution was coated on the surface for forming a release layer, dried in a nitrogen atmosphere at 120° C. for 3 minutes and at 160° C. for 3 minutes, and finally heated to 300° C. for 2 minutes, so as to produce a copper foil having a resin layer. The thickness of the resin layer was 2 μm.

### (7) Evaluations

### Evaluation of Root Mean Square Height Sq and Ratio (Sq/Rsm) of Root Mean Square Height Sq to Average Interval Rsm of Roughness

The surface of the metal foil (i.e., the surface on the side subjected to the surface treatment in the case where the surface treatment, such as the roughening treatment, was performed, or the surface on the side having the release layer provided thereon in the case where the release layer was provided) was measured for the root means square height Sq and the ratio (Sq/Rsm) of the root mean square height Sq to the average interval Rsm of the roughness with a laser microscope, LEXT OLS 4100, produced by Olympus Corporation. Rsm was measured in the mode according to JIS B0601 2001, and Sq was measured in the mode according to ISO 25178. Rsm and Sq each were measured at random 10 points, and the average values of Rsm and Sq were designated as the values of Rsm and Sq respectively. The measurement length of Rsm was 258 μm, the measurement area of Sq was 258 μm in length×258 μm in width. The ratio (Sq/Rsm) of the root mean square height Sq to the average interval Rsm of the roughness was calculated based on the obtained values. The temperature in the measurement was from 23 to 25° C.

### Production of Laminated Material

The following resin substrates 1 to 3 each were laminated on the metal foil on the side of the release layer.

Substrate 1: GHPL-830 MBT, produced by Mitsubishi Gas Chemical Co., Inc.

Substrate 2: 679-FG, produced by Hitachi Chemical Co., Ltd.

Substrate 3: EI-6785TS-F, produced by Sumitomo Bakelite Co., Ltd.

The temperature, the pressure, and the time employed in the lamination press were the recommended conditions provided by the manufacturers.

### Evaluation of Releasability of Metal Foil

The laminated material was measured for the ordinary peel strength on releasing the resin substrate from the copper foil with a tensile tester, Autograph 100, according to IPC-TM-650, and the releasability of the metal foil was evaluated by the following standard.

A: The peel strength was in a range of from 2 to 200 gf/cm.

B: The peel strength was less than 2 gf/cm or more than 200 gf/cm.

### Evaluation of Fracture Mode of Resin

The release surface of the resin substrate after the aforementioned release was observed with an electron microscope, and the fracture mode of the resin (i.e., cohesion, interface, or mixture of cohesion and interface) was observed. The “interface” means that the copper foil and the resin was released at the interface between them, the “cohesion” means that the resin is fractured due to the too large release strength, and the “mixture” means that the “interface” and the “cohesion” are mixed.

### Evaluation of Release of Circuit and Blister of Board

On the released surface of the resin substrates 1 to 3 after the aforementioned release, a copper plated pattern (line/space=40 μm/40 μm) was formed with a plating solution (liquid composition: Cu: 50 g/L, H₂SO₄: 50 g/L, Cl: 60 ppm) (sample 1). On the released surface of the resin substrates after the aforementioned release, a printed pattern (line/space=40 μm/40 μm) was formed with an ink containing a conductive paste by ink-jet (sample 2). On the released surface of the resin substrates after the aforementioned release, a resin layer constituted by a liquid crystal polymer (simulating a resin constituting a build-up layer) was laminated (sample 3).

Subsequently, the samples were confirmed for the presence of release of the circuit or blister of the board by a reliability test (which was a heating test at 250° C.±10° C. for 1 hour). The size of the sample was 250 mm×250 mm, and three specimens were measured for each of the samples.

The sample that did not form release of the circuit and blister of the board was evaluated as “AA”. The sample that slightly formed release of the circuit or blister of the board (three positions or less per one specimen) was evaluated as “A”. The sample that formed release of the circuit or blister of the board at many positions (more than three positions per one specimen) and was unusable as a product was evaluated as “B”.

The test conditions and the evaluation results are shown in Table 1.

TABLE 1

| | Electrolytic raw foil | | | | | | | | | | | | | |
|---|---|---|---|---|---|---|---|---|---|---|---|---|---|---|
| | Electrolysis condition | | | | | | | | | | | | | |
| | | | Linear | | | Rust | | | | | | | | |
| | | | velocity of | Rough- | Bar- | pre- | Silane | | | | | | | |
| | Thick- | Current | electrolytic | ening | rier | venting | coupling | | | | | | | Release |
| | ness | density | solution | treat- | treat- | treat- | treat- | Release | Sq | Rsm | Sq/ | Fracture | Release | of circuit |
| | (μm) | (A/dm²) | (m/sec) | ment | ment | ment | ment | layer | (μm) | (μm) | Rsm | mode | strength | and blister |
| Example 1 | 18 | 100 | 2 | no | no | yes | no | A | 0.85 | 6.1 | 0.14 | interface | A | AA |
| Example 2 | 18 | 100 | 2 | no | no | yes | no | B | 0.85 | 6.1 | 0.14 | interface | A | AA |
| Example 3 | 18 | 100 | 2 | no | no | yes | no | C | 0.85 | 6.1 | 0.14 | interface | A | AA |
| Example 4 | 18 | 100 | 2 | no | no | yes | no | D | 0.85 | 6.1 | 0.14 | interface | A | AA |
| Example 5 | 18 | 100 | 2 | no | no | yes | no | E | 0.85 | 6.1 | 0.14 | interface | A | AA |
| Example 6 | 18 | 80 | 4 | yes | yes | yes | yes | A | 0.73 | 3.6 | 0.20 | interface | A | AA |
| Example 7 | 35 | 100 | 2 | no | yes | yes | no | A | 0.98 | 4.0 | 0.25 | interface | A | A |
| Example 8 | 12 | 80 | 2 | no | no | yes | yes | A | 0.67 | 6.1 | 0.11 | interface | A | AA |
| Example 9 | 5 | 40 | 4 | no | no | yes | yes | no | 0.34 | 7.1 | 0.05 | interface | A | A |
| Example 10 | 105 | 100 | 2 | no | no | yes | yes | A | 1.40 | 3.8 | 0.37 | interface | A | A |
| Example 11 | 18 | 100 | 2 | no | no | yes | yes | no | 0.30 | 8.9 | 0.03 | interface | A | A |
| Example 12 | 150 | 100 | 2 | no | no | yes | no | no | 1.70 | 4.5 | 0.38 | interface | A | A |
| Example 13 | 18 | 80 | 2 | no | no | yes | no | A | 0.40 | 4.1 | 0.10 | interface | A | AA |
| Comparative | 35 | 100 | 2 | no | no | yes | no | A | 0.20 | 8.2 | 0.02 | interface | A | B |
| Example 1 | | | | | | | | | | | | | | |
| Comparative | 210 | 100 | 2 | no | no | yes | no | no | 1.70 | 4.0 | 0.43 | cohesion | B | B |
| Example 2 | | | | | | | | | | | | | | |

### Evaluation Results

Examples 1 to 13 were examples having the release layer provided on the uneven surface of the metal foil having surface unevenness having a root mean square height Sq of from 0.25 to 1.6 μm or the metal foil having surface unevenness having a ratio (Sq/Rsm) of a root mean square height Sq to an average interval Rsm of the roughness of from 0.05 to 0.40, which had good releasability in the physical release of the metal foil from the resin substrate and were favorably suppressed in occurrence of release of the circuit and blister of the board.

Comparative Example 1 had the root mean square height Sq of metal foil that was less than 0.25 μm and the ratio (Sq/Rsm) of the root mean square height Sq to the average interval Rsm of the roughness that was less than 0.05, and thus failed to prevent favorably release of the circuit.

Comparative Example 2 had the root mean square height Sq of metal foil that exceeded 1.6 μm and the ratio (Sq/Rsm) of the root mean square height Sq to the average interval Rsm of the roughness that exceeded 0.40, and thus had poor releasability in the physical release of the metal foil from the resin substrate, failing to prevent favorably occurrence of blister of the board.

1. A metal foil comprising, on at least one surface of the metal foil, surface unevenness having a root mean square height Sq of from 0.25 to 1.6 μm.

2. A metal foil comprising, on at least one surface of the metal foil, surface unevenness having a ratio (Sq/Rsm) of a root mean square height Sq to an average interval Rsm of the roughness of from 0.05 to 0.40.

3. The metal foil according to claim 1, wherein the metal foil comprises, on at least one surface of the metal foil, surface unevenness having a ratio (Sq/Rsm) of a root mean square height Sq to an average interval Rsm of the roughness of from 0.05 to 0.40.

4. The metal foil according to claim 1, wherein the metal foil has a thickness of from 5 to 105 μm.

5. The metal foil according to claim 1, wherein the metal foil is a copper foil.

6. The metal foil according to claim 1, wherein the metal foil comprises, on a surface of the metal foil, one or more layer selected from the group consisting of a roughening treatment layer, a heat resistant layer, a rust preventing layer, a chromate treatment layer, and a silane coupling treatment layer.

7. The metal foil according to claim 6, wherein the metal foil comprises a resin layer on the one or more layer selected from the group consisting of a roughening treatment layer, a heat resistant layer, a rust preventing layer, a chromate treatment layer, and a silane coupling treatment layer.

8. The metal foil according to claim 7, wherein the resin layer is an adhesive resin, a primer, or a semi-cured resin.

9. A metal foil having a release layer comprising
the metal foil according to claim 1 and
a release layer provided on a side of the metal foil having the surface unevenness.

10. The metal foil having a release layer according to claim 9, wherein the release layer comprises one kind or a combination of plural kinds of an aluminate compound, a titanate compound, or a zirconate compound represented by the following formula, a hydrolyzed product of the aluminate compound, the titanate compound, or the zirconate compound, and a condensed product of the hydrolyzed product:
(R¹)ₘ-M-(R²)ₙ
wherein R¹ represents an alkoxy group or a halogen atom; R² represents a hydrocarbon group selected from the group consisting of an alkyl group, a cycloalkyl group, and an aryl group, or the hydrocarbon group, in which one or more hydrogen atom is substituted by a halogen atom; M represents any one of Al, Ti, and Zr; n represents 0, 1, or 2; and m represents an integer of 1 or more and a valency of M or less, provided that at least one of R¹ is an alkoxy group, and m+n is a valency of M, which is 3 for Al or 4 for Ti and Zr.

11. The metal foil having a release layer according to claim 9, wherein the release layer comprises one kind or a combination of plural kinds of a silane compound represented by the following formula, a hydrolyzed product of the silane compound, and a condensed product of the hydrolyzed product: 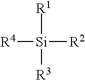
wherein R¹ represents an alkoxy group or a halogen atom; R² represents a hydrocarbon group selected from the group consisting of an alkyl group, a cycloalkyl group, and an aryl group, or the hydrocarbon group, in which one or more hydrogen atom is substituted by a halogen atom; R³ and R⁴ each independently represent a halogen atom, an alkoxy group, a hydrocarbon group selected from the group consisting of an alkyl group, a cycloalkyl group, and an aryl group, or the hydrocarbon group, in which one or more hydrogen atom is substituted by a halogen atom.

12. The metal foil having a release layer according to claim 9, wherein the release layer comprises a compound containing two or less mercapto groups in a molecule.

13. The metal foil having a release layer according to claim 9, wherein the metal foil having a release layer comprises a resin layer provided on a surface of the release layer.

14. The metal foil having a release layer according to claim 13, wherein the resin layer is an adhesive resin, a primer, or a semi-cured resin.

15. A laminated material comprising
the metal foil according to claim 1, or a metal foil having a release layer comprising the metal foil according to claim 1 and a release layer provided on a side of the metal foil having the surface unevenness and
a resin substrate provided on the metal foil or the metal foil having a release layer.

16. The laminated material according to claim 15, wherein the resin substrate is a prepreg or contains a thermosetting resin.

17. A printed wiring board comprising the metal foil according to claim 1 or a metal foil having a release layer comprising the metal foil according to claim 1 and a release layer provided on a side of the metal foil having the surface unevenness.

18. A semiconductor package comprising the printed wiring board according to claim 17.

19. An electronic device comprising the printed wiring board according to claim 17.

20. A method for producing a printed wiring board, comprising:
adhering a resin substrate to the metal foil according to claim 1 or a metal foil having a release layer comprising the metal foil according to claim 1 and a release layer provided on a side of the metal foil having the surface unevenness;
releasing the metal foil or the metal foil having a release layer without etching, from the resin substrate, so as to provide a resin substrate having a surface profile transferred from a surface of the metal foil or the metal foil having a release layer to a released surface of the resin substrate; and
forming a circuit on the released surface of the resin substrate having the surface profile transferred.

21. The method for producing a printed wiring board according to claim 20, wherein the circuit formed on the released surface of the resin substrate having the surface profile transferred is a plated pattern or a printed pattern.

22. A method for producing a printed wiring board, comprising:
adhering a resin substrate to the metal foil according to claim 1 or a metal foil having a release layer comprising the metal foil according to claim 1 and a release layer provided on a side of the metal foil having the surface unevenness;
releasing the metal foil or the metal foil having a release layer without etching, from the resin substrate, so as to provide a resin substrate having a surface profile transferred from a surface of the metal foil or the metal foil having a release layer to a released surface of the resin substrate; and
providing a build-up layer on the released surface of the resin substrate having the surface profile transferred.

23. The method for producing a printed wiring board according to claim 22, wherein a resin constituting the build-up layer contains a liquid crystal polymer or polytetrafluoroethylene.

24. A metal foil having a release layer comprising
the metal foil according to claim 2 and
a release layer provided on a side of the metal foil having the surface unevenness.

25. A metal foil having a release layer comprising
the metal foil according to claim 3 and
a release layer provided on a side of the metal foil having the surface unevenness.
